(19) United States
(12) Patent Application Publication
(10) Pub. No.: US 2008/0185960 A1
(43) Pub. Date: Aug. 7, 2008

(54) Organic electroluminescence device

(75) Inventor: Yoshiki Koshiyama, Tokyo (JP)

Correspondence Address: SQUIRE, SANDERS & DEMPSEY L.L.P., 1 MARITIME PLAZA, SUITE 300, SAN FRANCISCO, CA, 94111, US

(73) Assignee: Toppan Printing Co., Ltd., Tokyo (JP)

(21) Appl. No.: 12/012,140

(22) Filed: Jan. 30, 2008

(30) Foreign Application Priority Data
Feb. 2, 2007 (JP) 2007-024016

(51) Int. Cl. H01J 1/62; H01L 51/52

(52) U.S. Cl. 313/512

(57) ABSTRACT

One embodiment of the present invention is an organic EL device including a substrate and a sealing substrate, both substrates being attached to each other, the substrate including a first electrode formed on the substrate, an organic EL layer formed on the electrode and a second electrode formed on the organic EL layer, and the sealing substrate having a moisture capture agent layer formed on a surface of the sealing substrate on the substrate side, wherein a space between the substrate and the sealing substrate is filled with an injection material.

### CROSS REFERENCE TO RELATED APPLICATION

This application claims priority to Japanese application number 2007-024016, filed on Feb. 2, 2007, which is incorporated herein by reference.

### BACKGROUND OF THE INVENTION

1. Field of the Invention

The present invention relates to an organic electroluminescence device including a substrate and a sealing substrate wherein the substrate is attached to the sealing substrate, the substrate including an electrode formed on the substrate, an organic electroluminescence layer formed on the electrode and an electrode formed on the organic electroluminescence substrate.

Further, the present invention relates to a top emission type organic electroluminescence device including a substrate and a sealing substrate wherein the substrate is attached to the sealing substrate, the substrate including a reflective electrode formed on the substrate, an organic electroluminescence layer formed on the electrode and a transparent electrode formed on the organic electroluminescence layer.

2. Description of the Related Art

An organic electroluminescence device (hereinafter this is called an organic EL device.) having a sandwich structure wherein a pair of electrodes sandwiching a light emitting layer are arranged on a glass substrate is well known. The electrode of one side is transparent in order to take out a light from the organic light emitting layer. Generally, a transparent electrode made of ITO (indium tin oxide) is used for an anode. In the case of a top emission type organic electroluminescence device, a light is taken out from a sealing substrate. Therefore, highly reflective material is arranged under the transparent electrode, and a transparent electrode is used for a cathode. The surrounding surface of the light emitting layer is sealed with a sealing material. The light emitting layer emits light when an electric voltage is applied between the electrodes using an external driving circuit.

On the other hand, in the case of a bottom emission type organic electroluminescence device, the device is manufactured by laminating the following elements,in the order described: a transparent electrode such as ITO as an anode, a light emitting medium layer including a hole injection layer, a hole transport layer, a light emitting layer, an electron transport layer or the like, and a non-transparent back electrode such as aluminum (Al) as a cathode are laminated on a transparent supporting substrate.

The organic EL device is superior in visibility and flexibility and has a variety of light emitting characteristics. Therefore, organic EL devices are widely used for a display or a display device such as a component type stereo arranged in a car or a mobile phone.

It is known that while the organic EL device has such superior characteristics it is generally easily damaged by water. As an example, the organic EL device has the following problem in terms of life time; when the periphery of the organic EL device is sealed with a sealing material, water which is included in atmospheric air or moisture which passes through a defect part of a sealing layer, enters the organic EL device. In such a case, in the organic EL display, non-light emitting regions called “dark spots” appear, thereby it becomes impossible to sustain emitting the light.

Therefore, in the conventional bottom emission type display, a structure with a sealing can was generally used (See patent document 5.). The structure with the sealing can is described below. A hollow structure is formed by attaching the sealing can (a sealing cap) made of glass or metal to the other substrate using an adhesive and the sealing can prevent moisture from entering the organic EL device. Moisture entering from a cross section of an adhesive is caught by a porous absorbing sheet made of a moisture absorption property absorbing material, the porous absorbing sheet being provided at an inner side of a sealing can.

In addition, in the conventional top emission type display, constituent materials of the organic EL layers have been protected from moisture and oxygen by a desiccant attached to a sealing glass. However, such a desiccant is non-transparent or light scattering. Therefore, in the case of the top emission type device where light is taken out from a side (a sealing glass side) opposite to a substrate side, there is no place to arrange a usual desiccant. In addition, there is not a sufficiently large space in the surrounding part of the device because a small device is needed. (See patent document 1.)

On the other hand, from the view point that a small device is needed, the use of a barrier layer is proposed wherein an inorganic material layer and an organic material layer are repeatedly laminated, the inorganic material layer having a dense structure and the organic material layer relaxing the stress generated in the inorganic layer. (See patent document 2.) However, in the case where the barrier layer is adapted to the top emission type device, it is necessary to control the transparence level and the refractive index of the respective layers. At the same time, a new additional apparatus such as a vacuum vapor-deposition apparatus for depositing the inorganic material and the organic material is necessary. These problems cause an increase in costs and thereby cause problems for commercial production.

On the other hand, from the point of cost reduction, the following technology is proposed (See patent document 3): a capture agent is provided on a transparent electrode; the capture agent includes a constitute substance of the organic EL layer; and a transparent protective film is provided so that the film covers the capture agent layer. However, the capture agent layer which forms the organic EL layer does not have a sufficient moisture capture performance. Therefore, if a transparent protective film is provided, the reliability of sealing life time is low.

On the other hand, in patent document 4, sealing by an inactive liquid including an absorbing agent is proposed. However, since the absorbing agent is dispersed in the inactive liquid, diffuse reflection easily occurs. Therefore, this technology is not suitable for the top emission type. If the liquid is used in the top emission type, the absorbing agent must be formed out of the pixel region or the absorbing agent must be used as a transparent thin film.

Hereinafter, well-known documents are described.

[Patent document 1] JP-A-5-36475

[Patent document 2] JP-A-10-233283

[Patent document 3] JP-A-2006-4721

[Patent document 4] JP-A-9-35868

[Patent document 5] JP-A-2002-280166

### SUMMARY OF THE INVENTION

One embodiment of the present invention is an organic EL device including a substrate and a sealing substrate, both substrates being attached to each other, the substrate including an electrode (a first electrode) formed on the substrate, an organic EL layer formed on the electrode and an electrode (a second electrode) formed on the organic EL layer, and the sealing substrate having a water capture agent layer on a surface of the sealing substrate in the substrate side, wherein a space between the substrate and the sealing substrate is filled with an injection material.

### BRIEF DESCRIPTION OF THE DRAWINGS

FIG. 1 is a cross-sectional view of an embodiment of a top emission type organic electroluminescence device of the present invention.

FIG. 2 is a cross-sectional view of another embodiment of a top emission type organic electroluminescence device of the present invention.

FIG. 3 is a cross-sectional view of a top emission type organic electroluminescence device of example 3 of the present invention.

FIG. 4(a) is an example of a sealing substrate used as example 3 of the present invention.

FIG. 4(b) is an example of a metal mask used as example 3 of the present invention.

FIG. 5 is a cross-sectional view of an embodiment of a bottom emission type organic electroluminescence device of the present invention.

In these drawings, 10 is a substrate; 20 is a reflective electrode; 21 is an electrode formed on a substrate; 30 is an organic electroluminescence layer; 32 is a hole transport layer; 33 is a light emitting layer; 35 is an electron injection layer; 40 is a transparent electrode; 41 is an electrode formed on an organic electroluminescence layer; 50 is a transparent protective layer; 60 is a sealing substrate; 70 is a moisture capture agent layer; 80 is an injection material; 90 is an adhesive; 91 is a region for adhesion; and 100 is a metal mask.

### DETAILED DESCRIPTION OF THE INVENTION

The objective of the present invention is to provide a thin, light, long life-time and low cost type organic EL device wherein the influence of moisture entering the organic EL device from an end (an edge) thereof is controlled for a long time.

Further, the objective of the present invention is to provide a thin, light, long life-time and low cost type top emission type organic EL device wherein the influence of moisture entering the organic EL device from an end (an edge) thereof is controlled for a long time.

One embodiment of the present invention is an organic EL device including a substrate and a sealing substrate, both substrates being attached to each other, the substrate including an electrode (a first electrode) formed on the substrate, an organic EL layer formed on the electrode and an electrode (a second electrode) formed on the organic EL layer, and the sealing substrate having a moisture capture agent layer on a surface of the sealing substrate in the substrate side, wherein a space between the substrate and the sealing substrate is filled with an injection material.

When the space is filled with an injection material, it is possible to delay the time it takes for water to reach a light emitting part from an end of a sealing part compared to when the space is not filled. Therefore, an organic EL device with a long life-time can be obtained.

Another embodiment of the present invention is a top emission type organic EL device including a substrate and a sealing substrate, both substrates being attached to each other, the substrate including a reflective electrode formed on the substrate, an organic EL layer formed on the electrode and a transparent electrode formed on the organic EL layer, and the sealing substrate having a moisture capture agent layer on a surface of the sealing substrate in the substrate side, wherein a space between the substrate and the sealing substrate is filled with an injection material.

When the space is filled with an injection material, it is possible to delay the time it takes for moisture to reach a light emitting part from an end of a sealing part compared to when the space is not filled. Therefore, a top emission type organic EL device with a long life-time can be obtained. In addition, the injection material can reduce differences in a refractive index between both sides of an interface of the transparent electrode. Therefore, light from the organic EL device can be efficiently taken out.

Another embodiment of the present invention is an organic EL device having the sealing layer, the capture water agent layer and injection layer of 80% transmittance or more.

In the case where transmittance of the sealing layer, the capture moisture agent layer and injection layer is 80% or more, a top emission type organic EL device can be obtained.

Another embodiment of the present invention is an organic EL device having a planar sealing substrate.

In the case where a planar sealing substrate is used instead of a sealing cap including a sealing substrate having a concave part, an organic EL device can be inexpensively manufactured.

Further, in the case where a planar sealing substrate is used instead of a sealing cap including a sealing substrate having a concave part, a top emission type organic EL device can be inexpensively manufactured.

Another embodiment of the present invention is an organic EL device wherein the injection material includes at least one of the following; a UV curable resin, a thermosetting resin, a fluorinated inactive liquid and fluorinated oil.

A UV curable resin, a thermosetting resin, a fluorinated inactive liquid and fluorinated oil have the following properties: low moisture permeability; adsorbed amounts of moisture (water) and oxygen are small; amounts of outgas from these materials are small; and chemical reaction or melting does not occur. So, if the injection material includes at least one of these materials, it takes a long time for moisture entering from a sealing end to reach a light emitting part. Therefore, an organic EL device having few non-light emitting regions called dark spots can be obtained.

Another embodiment of the present invention is an organic EL device including a protective film covering an electrode formed on the substrate, an organic EL layer and an electrode formed on the organic EL layer.

When a protective layer is further used, transmission of moisture to a light emitting part is further controlled, thereby an organic EL device having a long life-time can be obtained.

Another embodiment of the present invention is an organic EL device including a transparent protective film covering the reflective electrode, an organic EL layer and a transparent electrode.

When a transparent protective layer is further used, transmission of moisture to a light emitting part is further controlled, thereby a top emission type organic EL device having a long life-time can be obtained.

Another embodiment of the present invention is an organic EL device wherein the moisture capture agent layer includes an organic metal complex in which trivalent metals are connected by oxygen molecules.

An organic metal complex in which trivalent metals are connected by oxygen molecules is superior in moisture-absorption characteristics by chemical adsorption of water. Thereby an organic EL device with a long life-time can be obtained. Further, since the film is transparent, an organic EL device with a long life-time can be obtained. Further, since the complex can be dissolved by a solvent, film formation by application is possible.

Hereinafter, embodiments of the present invention are described referring to figures. In addition, the figures are used for explaining constitutions of the present invention. Dimension, thickness and the like are different from real values. In addition, the present invention is not limited to the embodiments.

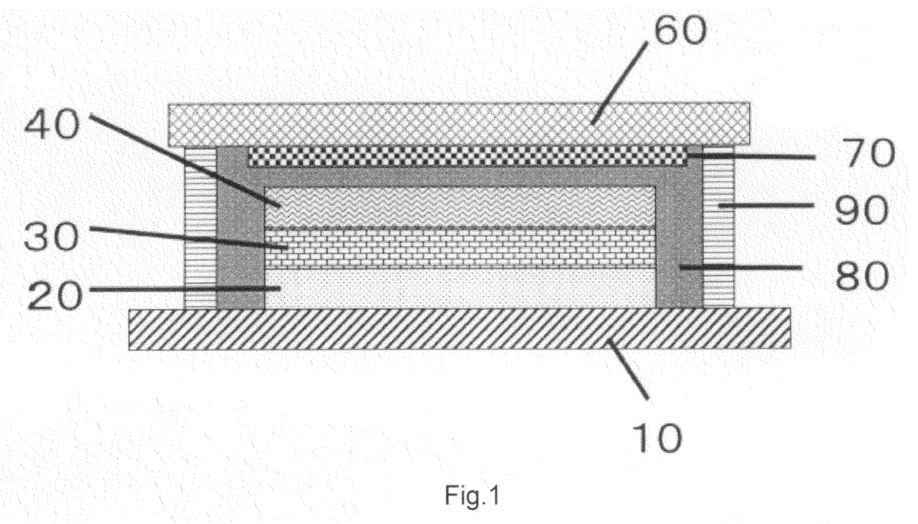

FIG. 1 shows an example of a top emission type organic EL device. FIG. 1 is a cross-sectional view. A top emission type organic EL device has a structure in which reflective electrode 20, organic EL layer 30 and transparent electrode 40 are, in this order, formed on substrate 10, and the substrate 10 is attached to sealing substrate 60 through adhesive 90. Moisture capture agent layer 70 is provided on a surface of the sealing substrate 60. Moisture capture agent layer 70 is arranged so that the layer 70 faces a laminated body. In addition, a space between substrate 10 and sealing substrate 60 is filled with injection material 80. In FIG. 1, one light emitting part is shown. (a pixel in a case of a single color display; a sub pixel in a case of a multiple color display) However, this embodiment can have a plurality of light emitting parts.

Substrate 10 can be transparent and can be non-transparent. Substrate 10 should be resistant to conditions such as solvent, temperature and the like, in the case of layer formation. Substrate 10 is preferably superior in dimension stability. Examples of preferred materials for substrate 10 include metal, ceramic, glass, semiconductors such as silicon, and resins such as polyethylene terephthalate and polymethyl methacrylate. In addition, a flexible film which is formed by using polyolefin, acryl resin, polyester resin or polyimide resin can be used for the substrate. In the case of forming the active matrix driving type device, a semiconductor such as silicon is preferable for substrate 10 having a plurality of switching devices (ex. TFT, MIM) on the surface thereof.

Reflective electrode 20 has a plurality of partial electrodes. It is desirable that reflective electrode 20 be made of a metal, an amorphous alloy and a fine crystalline alloy having high reflectance. The metals of high reflectance include Al, Ag, Mo, W. Ni, Cr or the like. The amorphous alloys of high reflectance include NiP, NiB, CrP, CrB or the like. The fine crystalline alloys of high reflectance include NiAl or the like. Reflective electrode 20 can be used as an anode or as a cathode. In the case where reflective electrode 20 is used as an anode, the efficiency of hole injection to the organic EL layer can be improved by forming a conductive metal oxide such as SnO₂, In₂O₃, ITO, IZO and ZnO:Al on the above-mentioned high reflectance material. In the case where reflective electrode 20 is used as a cathode, the efficiency of electron injection to organic EL layer 30 can be improved when a constituent layer of organic EL layer 30, the constituent layer being in contact with reflective electrode 20, is an electron injection layer 35.

In the case where the active matrix driving type device is formed, reflective electrode 20 has a plurality of partial electrodes which are, one on one, electrically connected to a plurality of switching electrodes formed on substrate 10. On the other hand, in the case where the passive matrix driving type device is formed, reflective electrode 20 has a plurality of stripe-shaped electrodes which extend in a first direction.

Reflective electrode 20 can be formed, depending on the kind of starting material, by any means known in this art such as vapor-deposition (heating by resistance or heating by electron beam), sputtering, ion plating and laser ablation. Reflective electrode 20 can have a plurality of partial electrodes which are formed by using a mask corresponding to a predetermined shape. Reflective electrode 20 can have a plurality of predetermined-shaped partial electrodes which are formed by a photolithography where at first a uniform layer is formed on a substrate. Reflective electrode 20 can be formed by a lift off method.

Here, a rib (a partition wall) can be formed so as to cover an end of the reflective electrode.

Next, organic EL layer 30 is formed on reflective electrode 20. Organic EL layer 20 can be a single layer film including a light emitting layer or can be multiple layer films including a light emitting layer. Examples of an organic EL layer having multiple layers are described below. Two layer construction such as a hole transport layer and an electron transporting property light emitting layer, or a hole transporting property light emitting layer and an electron transport layer. Three layer construction including a hole transport layer, a light emitting layer and a electron injection layer. Further, an electron blocking layer or a hole blocking layer can be inserted as needed. As for material, inorganic or organic known material can be preferably used. The formation method is not especially limited. The known dry process or wet process can be preferably used according to the kind of material.

As the known dry process or wet process, for example, vacuum vapor deposition method, spin coat method, cast method, sputtering method, LB method and printing method can be adopted. However, some methods (vacuum vapor-deposition method, spin coat method, cast method, LB method, printing method) other than sputtering method are preferably used for a light emitting layer. It is desirable that a light emitting layer be especially a film in which molecules are deposited. Here, “a film in which molecules are deposited” means a thin film which is formed by depositing a gaseous material, or a film which is formed by solidifying a material in a melted state or a liquid state solid. “The film in which molecules are deposited” can be usually distinguished from a thin film (molecule built-up film) formed by LB method by differences of aggregation structure or higher-order structure and difference of function due to the structure. In the case where a light emitting layer is formed by a spin coat method, a printing method or the like, an application liquid is prepared by dissolving a binder such as a resin and a material compound in a solvent.

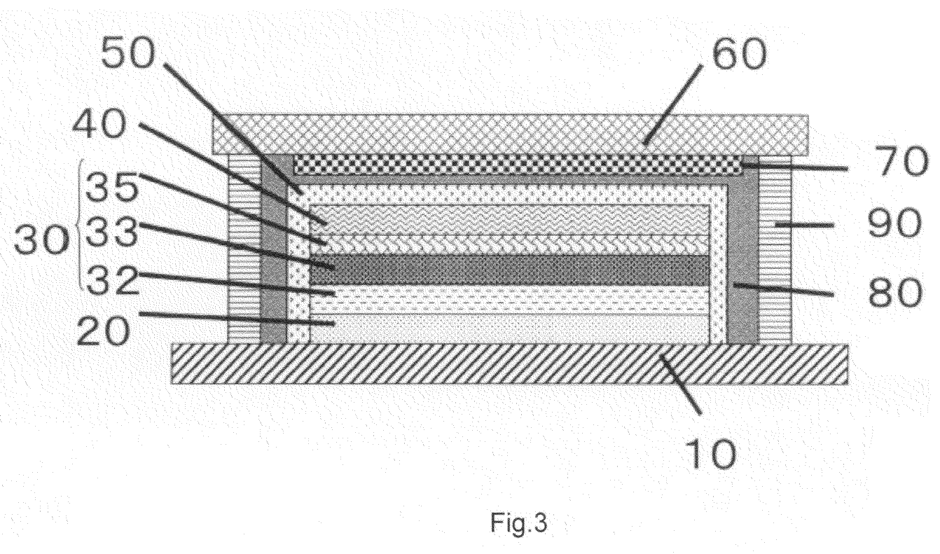

An example of organic EL layer 30 is shown in FIG. 3.

Any hole transport layer 32 or any hole injection layer can be used if it has hole transport properties or hole injection properties. Examples of materials for these layers include triazoles, oxadiazoles, imidazoles, poly aryl alkanes, pyrazolines, pyrazolone derivative, phenylenediamines, aryl amine derivative, amino permutation chalcones, oxazoles, styryl anthracenes, fluorenones, hydrazone derivative, stilbenes, silazanes, poly silane system compound, aniline system copolymer, electroconductive polymer oligomers such as thiophen oligomers, porphyrin compound, aromatic tertiary amine compound, styryl amine compound and aromatic dimethylidyne system compound. The thickness of hole transport layer 32 or a hole injection transport layer is not especially limited. However, the thickness thereof is usually arbitrarily selected from the range 5 nm-5 μm. Hole transport layer 32 or the hole injection transport layer can have a single layer structure comprised of the above-mentioned one or more kind of materials. Hole transport layer 32 or the hole injection transport layer can have a structure including a plurality of layers of which compositions are identical or different.

Further, as inorganic materials, metal oxides such as Cu₂O, Cr₂O₃, Mn₂O₃, FeOx(x˜0.1), NiO, CoO, Pr₂O₃, Ag₂O, MoO₂, Bi₂O₃, ZnO, TiO₂, SnO₂, ThO₂, V₂O₅, Nb₂O₅, Ta₂O₅, MoO₃, WO₃ and MnO₂, and carbide, nitride and boride thereof can be used.

As a light emitting layer, the light emitting layer for the organic EL device can be used. That is, a light emitting layer having the following function can be used: the injection function (when an electric field is applied to the layer, holes can be injected from an anode or hole injection layer 32 while electrons can be injected from a cathode or an electron injection layer.); the transport function (injected electric charge (one or both of an electron and a hole) is moved by an electric field.); and the light emitting function (light is emitted when an electron and a hole recombine.). Examples of the materials include fluorescent bleach of benzothiazole system, benzo imidazole system or benzo oxazole system, and metallic complex of metal chelation oxynoid compound, styryl benzene series compound, distyrylpyrazine derivative, polyphenyl system compound, 12-phthaloperinone, 1,4-diphenyl-1,3-butadiene, 1,1,4,4-tetraphenyl-1,3-butadiene, naphthalimido derivative, perylenes, oxadiazoles, aldazine derivative, pyran derivative, cyclopentadienes, pyrrolo pyrroles, styryl amine derivative, coumarin system compound, aromatic dimethylidyne compound and 8-quinolinols. The thickness of the light emitting layer is not especially limited. However, the thickness is usually arbitrarily selected from the range of 5 nm-5 μm.

Electron injection layer 36 can be a thin film (the film thickness is 10 nm or less.) comprised of hole injection property materials such as alkali metal, alkaline earth metals or an alloy including them, or alkali metal fluoride. Quinolinol complex of the aluminium in which alkali metal or alkaline-earth metals is doped can be also used. In the present invention, in the case where transparent electrode 40 is a cathode, it is desirable that electron injection properties be improved by arranging electron injection layer 35 at an interface between transparent electrode 40 and organic EL layer 30.

Further, electron transport layer should have a function which transports electrons injected from a cathode to a light emitting layer. Examples of the materials include metallic complex of nitration fluorenones, anthra quinodimethanes, diphenyl quinone derivative, thio pyran dioxide derivative, heterocycle tetra carboxylic acid anhydride such as naphthalene perylene, carbodiimide, anthra quinodimethanes, anthrones, oxadiazoles and 8-quinolinols, and metal-free phthalocyanine, metal phthalocyanine, and compound in which an alkyl group or a sulfone group is substituted for these material's (metal-free phthalocyanine, metal phthalocyanine) end, and distyrylpyrazine derivative. The thickness of the electron transport layer is not especially limited. However, the thickness is usually arbitrarily selected from the range of 5 nm-5 μm. The electron transport layer can have a single layer structure comprised of the above-mentioned one or more materials, or can have a structure including a plurality of layers of which compositions are identical or different.

Next, transparent electrode 40 is formed on organic EL layer 30 by a sputtering method. Transparent electrode 40 is formed by using conductive metal oxides such as SnO2, In2O3, ITO, IZO and Zno:Al. In the case where transparent electrode 40 is used as a cathode, it is desirable that the efficiency of electron injection be improved by using electron injection layer 35 as the uppermost layer of organic EL layer 30. It is desirable that transparent electrode 40 has transmittance of 50% or more in a light wave length range of 400-800 nm. More preferably, it is 80% or more. It is desirable that transparent electrode 40 usually has a thickness of 50 nm or more. More preferably, it is 50 nm-1 μm. Furthermore, preferably, it is 100-300 nm.

In the case where an active matrix driving type organic EL device is formed, since reflective electrodes 20 are independently formed corresponding to respective pixels (or sub pixels), transparent electrode 40 is formed as an all-in-one electrode. On the other hand, in the case where a passive matrix driving organic EL device is formed, transparent electrode 40 is formed as a plurality of stripe-shaped electrodes in a second direction intersecting (preferably, perpendicularly intersecting) the first direction.

In this embodiment, substrate 10 having a laminated body is attached to sealing substrate 60 through adhesive 90 which is described below. It is necessary for sealing substrate 60 to be transparent to light which is emitted from organic EL layer 30. It is desirable that sealing substrate 60 has transmittance of 50% or more in the light wave length of 400-800 nm. More preferably, it is 80% or more. Examples of preferred materials of sealing substrate 60 include glass and resins such as Polyethylene terephthalate and polymethyl methacrylate. A borosilicate glass or a soda glass is especially preferred. A flexible film made of polyolefin, acryl resin, polyester resin or polyimide resin can be used as sealing substrate 60.

Further, it is desirable that the moisture-vapor transmission of sealing substrate 60 be 10⁻⁶ g/m²/day or less.

As for the shape of the sealing substrate, a planar type or a sealing cap type can be preferably used. However, since the planar type is more inexpensive than the cap type, the planar type is desirable.

Next, moisture capture agent layer 70 is formed on sealing substrate 60. If moisture capture agent layer 60 has transmittance of 80% or more, there is no special limit to moisture capture agent layer 60. The known dry process or wet process can be preferably used according to the material.

The above-mentioned transmittance is 80% or more in light wave length of 400-800 nm.

In the case of dry process, for example, Bao or CaO which has high transparency and high moisture absorption abilities can be formed by a vapor-deposition method.

In the case of wet process, the moisture capture agent layer can be formed by the following process: a liquid material in which an organometallic complex is dissolved, the organometallic complex being a product in which Al or another trivalent metal is combined by an oxygen molecule, is applied to a predetermined sealing substrate 60 and is dried. The commercial usable materials include Oledry (a product of Futaba Corporation) and liquid ORIPU AOO (a product of HOPE CHEMICAL Co., Ltd). Examples of application methods include a dispense method, an ink jet method, a slit printing and a spray printing. In the case of application, it is desirable that the sealing substrate be covered by a metal mask or a resin mask so that a specified region is applied. In addition, the liquid can be prevented from spreading by preliminarily providing a frame on the sealing substrate. In addition, a sealing substrate can be heated to a high temperature so that the liquid is prevented from spreading. It is necessary for the thickness of the moisture capture agent layer to be equal to or less than the thickness of a spacer which is described below. The thickness of 10 μm or less is desirable. At the time of coating and drying, it is desirable that the environment have low humidity (ex. Inactive dry N₂).

Further, it is desirable that the thickness of the moisture capture agent layer is 100 nm or more so that sufficient moisture absorption is kept. More preferably, it is 1 μm or more.

Especially, in the case where an organometallic complex in which trivalent metals are combined by oxygen molecules is used, moisture absorption property because of chemical absorption of moisture is high, thereby an organic EL device having a long life-time can be obtained. Further, since the organometallic complex is solved in a solvent, film formation by application is possible. An example of the organometallic complex is described below. Three pairs of aluminum atoms and oxygen atoms constitute a six-member ring and a substituent group coordinating at aluminum atom is an alkyl group. In such a construction, if moisture exists, the six-member ring opens. One water molecule is absorbed by one aluminum atom, thereby high moisture absorption properties are obtained.

Next, adhesive 90 is formed. Adhesive 90 is provided on the periphery of sealing substrate 60 and is used for attaching substrate 10 to sealing substrate 60. In the present invention, UV curable adhesive is desirable. Especially, the following UV curable adhesive is preferred: if the adhesive is irradiated with UV ray of 100 mW/cm² or more, the adhesive is cured within 10-90 seconds. If the adhesive is cured within the time, negative influences on other constituent elements by irradiation with UV ray do not occur. At the same time, the UV curable adhesive is sufficiently cured, and appropriate adhesion strength is achieved. In addition, in view of the manufacturing processes, the above-mentioned time is desirable.

In addition, adhesive 90 used for the present invention can include glass beads or silica beads of 10-100 μm diameter (more preferably, 10-50 μm diameter) as spacers. These beads decide the amount of injection material 80 described later in the case of attaching the substrate to the sealing substrate. At the same time, these beads are resistant to the applied pressure in the case of the adhesion. Further, the spacers are resistant to the stress (especially, the stress at the periphery of the device) occurring in driving the organic EL device. Therefore, the spacers are effective for preventing the degradation of the organic EL device due to the stress.

Next, injection material 80 is formed on sealing substrate 60. Internal space decided by substrate 10, sealing substrate 60 and adhesive 90 is filled with injection material 80. UV curable resin, thermal setting property resin, fluorinated inactive liquid (ex, Fluorinert™) and fluorinated oil is used for injection material 80. A more preferred filling material in the present invention is fluorinated inactive liquid. Examples of the thermal setting property resin include a silicone type resin in which gelatification occurs by heating. A method for coating injection material 80 to sealing substrate 80 is not limited if the amount of application can be controlled. For example, a dispense method or a droplet discharging method can be used. It is desirable that attaching is conducted by applying pressure while a space between both substrates is in a reduced pressure state. Preferred example: applying pressure of 0.98 kPa-98 kPa in a reduced pressure state of 0.1 kPa-50 kPa.

Here, examples of fluorinated inactive liquids include liquid fluorinated carbons such as perfluoroalkane, perfluoroamine and perfluoropolyether. It is desirable that the boiling point is 150° C. or higher so that the internal pressure does not increase. In addition, it is desirable that the amounts of moisture and oxygen which cause dark spots be small. The amount of dissolution of moisture is preferably 100 ppm or less. The amount of dissolution of air is preferably 30 m³gas/100 m³liquid.

The adhesive is cured at the time of attaching or after attaching.

Since injection material 80 is located at the path of the taken-out light, injection material 80 should have visible light transmittance of 20-95% (preferably, 60% −95%) in the light wave length of 400-800 nm.

More preferably, it is 80% or more in the light wave length of 400-800 nm.

If injection material 80 has such transmittance, light can be efficiently taken out from the organic EL light emitting device through injection material 80. In addition, it is desirable that the injection material of the present invention has a refractive index of 1.2-2.5. If the injection material has such a refractive index, the difference of the refractive index at the interface between injection material 80 and the transparent electrode is reduced, thereby the reflection at the interface can be controlled.

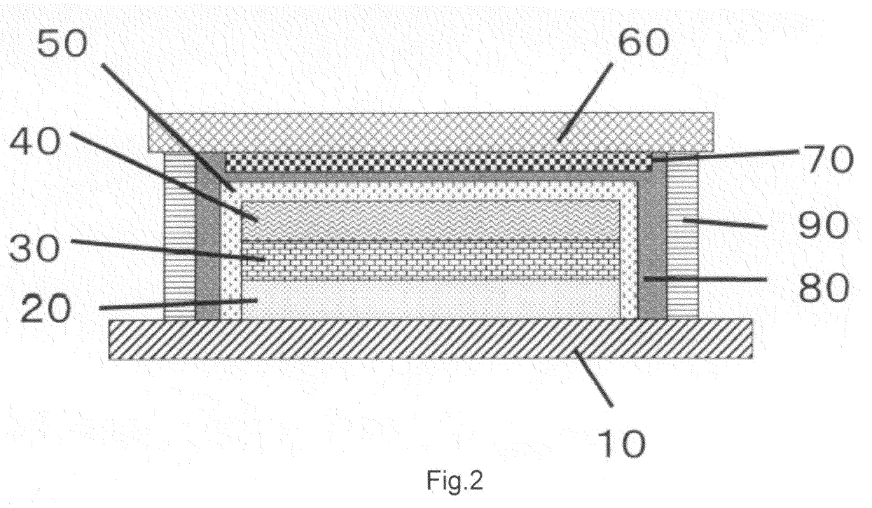

FIG. 2 and FIG. 3 show other embodiments of a top emission type organic EL device of the present invention. In the present embodiments, transparent protective layer 50 is provided so as to cover reflective electrode 20, organic EL layer 30 and transparent electrode 40 which are used in the embodiment shown in FIG. 1.

The material which can be used for forming transparent protective layer 50 can be selected from materials which satisfy the following conditions: high transparency in visible light range (transmittance of 50% or more in wave length of 400-700 nm); Tg of 100° C. or more; surface hardness of 2 H or more (pencil sharpness); and performance which does not lower the function of organic EL layer 30 which is under the transparent protective layer. In addition, it is desirable that transparent protective layer 50 has a gas barrier property. Therefore, transparent protective layer 50 can be made of inorganic oxides or inorganic nitrides such asSiOx, SiNx, SiNxOy, AlOx, TiOx, TaOx and ZnOx.

Further, transparent protective layer 50 can have a single layer structure, or can have a laminated structure including a plurality of layers using a plurality of different materials. In the case where transparent protective layer 50 has a laminated structure including a plurality of layers, the laminated structure can have a plurality of layers comprised of the above-mentioned inorganic oxides or inorganic nitrides. In addition, the laminated structure can have a layer of the above-mentioned inorganic oxide or inorganic nitride and a layer of an organic material. Examples of usable organic materials include an imide denaturation silicone resin, an acryl, an inorganic metallic compound dispersed in a polyimide or silicone resin, an epoxy denaturation acrylate resin, an ultraviolet cure type resin such as acrylate monomer, an oligomer and polymer including a reactive vinyl group, a resist resin, an inorganic compound, a photo-curing type and/or heat curing type resin such as fluorinated resin.

Further, these organic materials can be used for a single layer or can be used for a plurality of layers.

In the case where transparent protective layer 50 is formed, any methods known in the art can be used. For example, dry methods (sputtering method, vapor-deposition method, CVD method) and wet methods (spin coat method, roll coat method, cast method, dip coat method) can be used. In addition, in the case where transparent protective layer 50 is formed, it is desirable that the thickness of transparent protective layer 50 be as small as possible in order to minimize the viewing angle dependency (hue change when the viewing angle changes.) if a sufficient barrier property of a gas (oxygen, moisture vapor, organic solvent vapor or the like) is obtained. Usually, the thickness of transparent protective layer 50 is 0.1-1 μm.

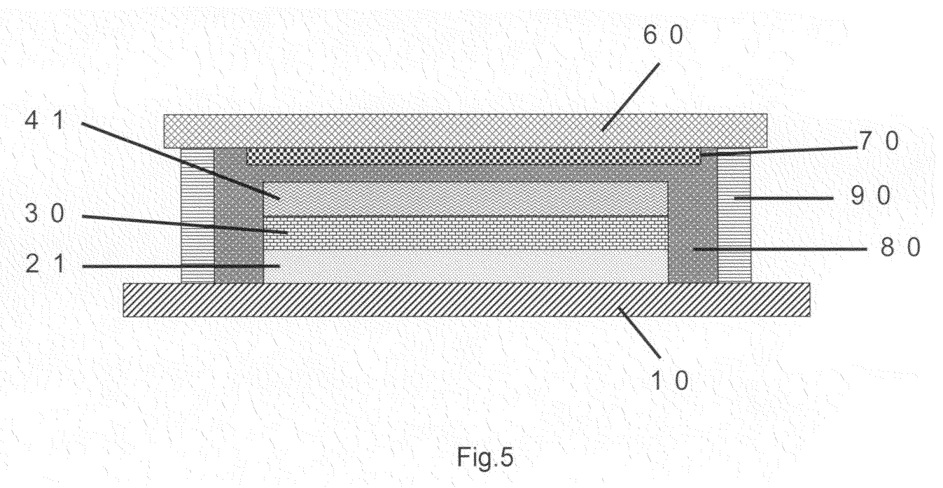

FIG. 5 shows an example of a bottom emission type organic EL device. Electrode 21 formed on a substrate, organic EL layer 30 and electrode 41 formed on the organic EL layer are formed on the substrate in this order. The substrate is attached to sealing substrate 60 through adhesive 90. Moisture capture agent layer 70 is formed on the surface of sealing substrate 60. Moisture capture agent layer 70 is placed so that the layer 70 faces a laminated body. In addition, a space between substrate 10 and sealing substrate is filled with injection material 80. In FIG. 5, one light emitting part is shown. (a pixel in a case of a single color display; a sub pixel in a case of a multiple color display) However, this embodiment can have a plurality of light emitting parts.

A transparent substrate is used for substrate 10 of a bottom emission type organic EL device. A transparent substrate among the above-mentioned substrates for the top emission type organic EL device can be preferably used.

Electrode 21 formed on the substrate should be transparent and electrode 21 can be an anode or a cathode. In the case of an anode, a metal, an alloy and an electric conductive compound which have large work functions (ex, 4 eV or more), and the mixture thereof are preferably used. For example, conductive transparent materials such as CuI, ITO, SnO₂ and Zn can be used. Here, these materials are preferably used for a top emission type organic EL device in which a transparent electrode is used for an anode.

Organic EL layer 30 can be formed by the same material and forming method as the above-mentioned top emission type organic EL device.

In the case where electrode 41 formed on organic EL layer 30 is a cathode, a metal, an alloy and an electric conductive compound which have small work functions (ex, 4 eV or less) and the mixture thereof are preferably used. For example, natrium, natrium-potassium alloy, magnesium, lithium, alloy or mixture metal of magnesium and silver, aluminium, Al/AlO₂, rare earth metals such as indium and ytterbium can be used. In the case where electrode 41 formed on the organic EL layer is both an anode and a cathode, transparent materials and non-transparent materials can be preferably used for both an anode and a cathode.

The film thicknesses of electrode 21 formed on the substrate and electrode 41 formed on the organic EL layer are decided by the material thereof However, the film thickness can be usually selected from the range of 10 nm-1 μm. In the case of both an anode and a cathode, it is desirable that the seat resistance be several hundred Ω/ε or less.

As sealing substrate 60, the same as the above-mentioned sealing substrate for the top emission type organic EL device can be used. Further, a non-transparent sealing substrate can be used. For example, ceramics such as alumina, silicon nitride and boron nitride, glass such as alkali-free glass and alkali glass, quartz, metallic foil such as aluminium, humidity resistance film can be used.

Moisture capture agent layer 70 can be formed by the same material and method as the above-mentioned top emission type organic EL device. Further, a non-transparent material can be preferably used. In the case where a moisture capture agent layer has moisture absorption properties and is fixed to sealing substrate 60 by organic compounds, the moisture capture agent is not especially limited, if the moisture capture agent does not easily react with the organic compounds. As the moisture capture agent layer, a organometallic complex in which trivalent metals are connected by oxygen molecules can be used. Further, calcium hydride (CaH₂), hydrogenation strontium (SrH₂), hydrogenation barium (BaH₂), lithium aluminum hydride (AlLiH₄), sodium oxide (Na₂O), potassium oxide (K₂O), calcium oxide (CaO), barium oxide (BaO) and magnesium oxide (MgO) can be also used. Commercial sheet-shaped water capture agents such as dessicant-A (a product of Japan Gore-Tex) and HD (a product of Dynic Corporation) can be also used.

As for adhesive 90, the same material and method as the adhesive for the top emission type organic EL device can be used.

As for the injection material (injection agent) layer 80, the same material and method as the injection material layer of the above-mentioned top emission type organic EL device can be used. Further, a non-transparent material can be preferably used. The material for the injection material layer 80 is not especially limited if chemical reaction, melting and dark spot does not occur when the layer is in contact with the organic EL layer. For example, thermoset resin or UV curable resin of an epoxy system or acryl system, and liquid fluorinated carbon such as perfluoroalkane, perfluoroamine and perfluoro polyether can be used.

As for the attaching method, the same method as the attaching method in the above-mentioned top emission type organic EL device can be used.

In addition, in the case of forming a protective layer, the same material and method as the above-mentioned top emission type organic EL device can be used. Further, a non-transparent material can be preferably used. Metallic oxide such as oxidation silicon, aluminium oxide, chromium oxide, magnesium oxide and tungsten oxide, metal fluoride such as aluminum fluoride and magnesium fluoride, metal nitrides such as a silicon nitride, aluminum nitride and chromium nitride, and metal oxynitride such as silicon oxide nitride can be used.

In the present invention, when the space is filled with an injection material, it is possible to delay the time it takes for moisture to reach a light emitting part from an edge of a sealing part than when the space is not filled. Therefore, an organic EL device of long life-time can be obtained.

Further, in the present invention, when the space is filled with an injection material, it is possible to delay the time it takes for moisture to reach a light emitting part from an end of a sealing part than when the space is not filled. Therefore, a top emission type organic EL device of long life-time can be obtained. In addition, the injection material can reduce a difference in the refractive index between both sides of an interface of the transparent electrode. Therefore, light from the organic EL device can be efficiently taken out.

In the case where transmittance of the sealing layer, the moisture capture agent layer and injection layer is 80% or more, a top emission type organic EL device can be obtained.

In the case where a planar sealing substrate is used instead of a sealing cap including a sealing substrate having a concave part, an organic EL device can be inexpensively manufactured. In addition, a sealing substrate is the most expensive component among components in the sealing process.

Further, in the case where a planar sealing substrate is used instead of a sealing cap including a sealing substrate having a concave part, a top emission type organic EL device can be inexpensively manufactured. In addition, a sealing substrate is the most expensive component among components in the sealing process.

The injection material includes at least one selected from a group of the following; UV curable resin, a thermosetting resin, a fluorinated inactive liquid and fluorinated oil. If the injection material includes at least one of these materials, it takes a long time for moisture entering from a sealing end to reach a light emitting part. Therefore, an organic EL device having little non-light emitting regions called dark spot can be obtained.

When the moisture capture agent layer includes an organometallic complex in which trivalent metals are connected by oxygen molecules, an organic EL device having an improved moisture absorption property and little dark spots can be obtained

When a protective layer is further used, transmission of moisture to a light emitting part is further controlled, thereby an organic EL device having a long life-time can be obtained.

When a transparent protective layer is further used, transmission of moisture to a light emitting part is further controlled, thereby a top emission type organic EL device having a long life-time can be obtained.

### EXAMPLES

### Example 1

Al was deposited on a glass substrate as a reflective metal by an vapor-deposition method. ITO was deposited thereon by a sputtering method. After the deposition, the substrate was polished, thereafter a reflective electrode of Al/ITO was formed by patterning using photolithography. Aqua regalis was used as an etchant.

The substrate on which the reflective electrode was formed was washed. The substrate was placed inside an oxygen plasma room. The atmosphere was Ar/O₂=1:1. Electric power of 100 W was applied. Washing was performed for 5 minutes.

Next, organic EL layer 30 was formed on the reflective electrode of Al/ITO. Organic EL layer 30 of 130 nm thickness includes a hole transport layer of 50 nm thickness and a light emitting layer of 80 nm thickness. The hole transport layer comprises a mixture (PEDOT-PSS) of (3,4-ethylenedioxy thiophen) and polystyrene sulfonate. The hole transport layer comprises poly[2-methoxy-5-(2′-Ethyl hexyloxy)-1,4-phenylenevinylene] (MEHPPV).

The substrate was moved into a vapor-deposition apparatus in which a metal vapor-deposition room, a sputtering room and a CVD room are connected. At first, the substrate was moved to the vapor-deposition room (pressure 5×10⁻⁵ Pa; room temperature) and Ca of 5 nm thickness was deposited. Next, the substrate was moved to the sputtering room and ITO of 80 nm thickness was deposited to form a transparent electrode by using an opposed type target sputtering method.

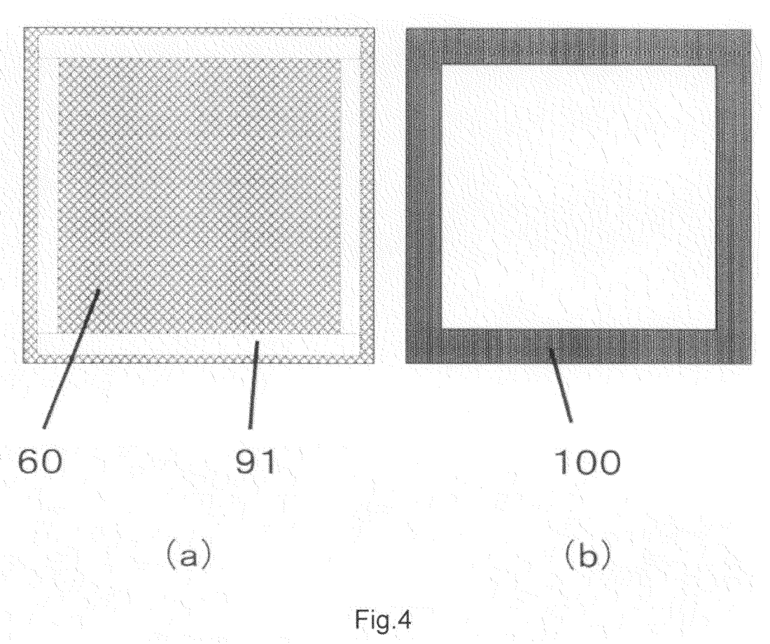

On the other hand, a moisture capture agent Oledry (a product of Futaba Corporation) was dispensed on a sealing substrate of alkali free glass to 2 μm/cm², thereafter it was dried to form a moisture capture agent layer. In the case of the dispensing, a metal plate was placed under the sealing substrate and a metal mask covers the sealing substrate, and in that state electrostatic chuck was conducted. Here, the metal mask was arranged so as to not cover the adhesion region. (See FIG. 4.)

Next, a UV curable adhesive including a spacer (25 μm thickness) was applied to the periphery of the sealing substrate. Thereafter, Fluorinert™ FC-70(refractive index 1.3) as an injection material was dropped inside the applied adhesive. By attaching the substrate with the transparent electrode to the sealing substrate, filling of the injection material was conducted. The attaching condition: a reduced pressure state of 30 kPa; and pressure of 19.6 kPa.

Finally, while keeping the applied pressure, the adhesive was cured by UV irradiation of 100 mW and 6000 mJ/cm².

Here, the transmittances of the sealing substrate, the moisture capture agent layer and the injection material were respectively 92%, 88% and 91% measured by spectrophotometer UV-3100 (a product of shimadzu corporation) (measuring condition: wave length 550 nm).

### Example 2

A top emission type organic EL device was manufactured by repeating the manufacturing processes in Example 1, however CaO of 0.08 μm thickness was deposited instead of Oledry as the moisture capture agent layer.

Here, the transmittance of the moisture capture agent layer was 82% measured by spectrophotometer UV-3100 (a product of shimadzu corporation) (measuring condition: wave length 550 nm).

### Example 3

A structure having the transparent electrode and the other components under the transparent electrode formed on a substrate was obtained by repeating the manufacturing process in Example 1. Next, the substrate was moved to the CVD room to deposit SiNx of 500 nm thickness as a transparent protective layer, thereby a top emission type organic EL device was obtained.

Here, the transmittance of the transparent protective layer was 89% measured by spectrophotometer UV-3100 (a product of shimazu corporation) (measuring condition: wave length 550 nm).

### Example 4

A bottom emission type organic EL device was manufactured by repeating the manufacturing process in Example 1, however ITO of 150 nm thickness was formed instead of the reflective electrode of Al/ITO and Al of 150 nm thickness was formed instead of ITO formed as a transparent electrode.

### Example 5

A top emission type organic EL device was manufactured by repeating the manufacturing processes in Example 1, however a colorless transparent glass cap was used instead of a planar glass of an alkali free glass as a sealing substrate.

### Comparative Example 1

A top emission type organic EL device was manufactured by repeating the manufacturing processes in Example 1, however the moisture capture agent layer was not provided.

### Comparative Example 2

A top emission type organic EL device was manufactured by repeating the manufacturing processes in Example 1, however the moisture capture agent layer and the injection material were not provided.

### Comparative Example 3

A bottom emission type organic EL device was manufactured by repeating the manufacturing processes in Example 4, however the moisture capture agent layer was not provided.

### (Evaluation)

Organic EL devices (See table 1) obtained in Example 1-5 and Comparative Example 1-3 were left in a constant temperature and humidity room. The light emitting surface was observed by an optical microscope. The area ratio of a dark spot (DS: non-light emitting part) in an initial time and the area ratio of a dark spot after 1500 hrs are shown in Table 2.

Table 1: The construction of the devices in Examples and Comparative Examples.

TABLE 1

| | electrode//hole transport layer//light | Moisture | | |
|---|---|---|---|---|
| | emitting layer//electron injection | capture | | |
| | layer//electrode//transparent | agent | Injection | Sealing |
| | electrode | layer | material | substrate |
| Example 1 | Al/ITO// PEDOT-PSS // MEHPPV // | Oledry | Fluorinert ™ | planar |
| | Ca//ITO | | | glass |
| Example 2 | Al/ITO// PEDOT-PSS // MEHPPV // | CaO | Fluorinert ™ | planar |
| | Ca//ITO | | | glass |
| Example 3 | Al/ITO// PEDOT-PSS // MEHPPV // | Oledry | Fluorinert ™ | planar |
| | Ca//ITO//SiNx | | | glass |
| Example 4 | ITO//PEDOT-PSS//MEHPPV//Ca//Al | Oledry | Fluorinert ™ | planar |
| | | | | glass |
| Example 5 | Al/ITO// PEDOT-PSS// MEHPPV // | Oledry | Fluorinert ™ | glass cap |
| | Ca//ITO | | | |
| Comparative | Al/ITO//PEDOT-PSS// MEHPPV// | — | Fluorinert ™ | planar |
| Example 1 | Ca// ITO | | | glass |
| Comparative | Al/ITO//PEDOT-PSS// MEHPPV// | — | — | planar |
| Example 2 | Ca// ITO | | | glass |
| Comparative | ITO//PEDOT-PSS//MEHPPV//Ca//Al | — | Fluorinert ™ | planar |
| Example 3 | | | | glass |

TABLE 2

| | | Area ratio of DS of devices |
|---|---|---|
| | Area ratio | left in 60° C., 60% RH for |
| | of initial DS (%) | 1500 hrs (%) |
| Example 1 | ≈0 | 0.3 |
| Example 2 | ≈0 | 2.4 |
| Example 3 | ≈0 | ≈0 |
| Example 4 | ≈0 | ≈0 |
| Example 5 | ≈0 | ≈0 |
| Comparative Example 1 | 0.1 | 100 |
| Comparative Example 2 | 0.5 | 100 |
| Comparative Example 3 | 0.1 | 100 |

As shown in Table 2, devices in Example 1-5 have a remarkably low area ratio of DS, little degradation and long life-time compared to devices in Comparative Example 1-3.

In addition, the device which used Oledry was further preferred. Oledry was an organometallic complex in which trivalent metals are connected by oxygen molecules. Oledry was used in a wet process.

In addition, in the case of top emission type organic EL devices of Example 1-3 and 5, the injection material could reduce the difference in the refractive index between both sides of an interface of the transparent electrode. Therefore, light from the organic EL device could be efficiently taken out. Further, transmittances of the sealing substrate, the moisture capture agent layer and the injection material are 80% or more, therefore a sufficient luminance of the emitted light was obtained.

What is claimed is:

1. An organic electroluminescence device, comprising:
a first electrode formed on a substrate;
an organic electroluminescence layer formed on said first electrode;
a second electrode formed on said organic electroluminescence layer;
a sealing substrate having a moisture capture agent layer, said moisture capture agent layer being formed on a surface which faces said substrate; and
an injection material filled in a space between said substrate and said sealing substrate,
wherein said substrate is attached to said sealing substrate.

2. The organic electroluminescence device according to claim 1,
wherein said first electrode formed on said substrate is a reflective electrode and said second electrode formed on said organic electroluminescence layer is a transparent electrode.

3. The organic electroluminescence device according to claim 1,
wherein transmittances of said sealing substrate, said moisture capture agent layer and said injection material are 80% or more.

4. The organic electroluminescence device according to claim 1,
wherein said sealing substrate is at least planar.

5. The organic electroluminescence device according to claim 1,
wherein said injection material includes at least one of the following materials:
a UV curable resin, a thermosetting resin, a fluorinated inactive liquid, or a fluorinated oil.

6. The organic electroluminescence device according to claim 1,
wherein a protective layer is formed so as to cover said first electrode formed on said substrate, said organic electroluminescence layer and said second electrode formed on said electroluminescence layer.

7. The organic electroluminescence device according to claim 2,
wherein a transparent protective layer is formed so as to cover said reflective electrode, said organic electroluminescence layer and said transparent electrode.

8. The organic electroluminescence device according to claim 1,
wherein said moisture capture agent layer includes an organometallic complex in which trivalent metals are connected by oxygen molecules.

9. An organic electroluminescence device, comprising:
a first electrode formed on a substrate;
an organic electroluminescence layer formed on said first electrode;
a second electrode formed on said organic electroluminescence layer;
a sealing substrate having a moisture capture agent layer, said moisture capture agent layer being formed on a surface which faces said substrate; and an injection material filled in a space between said substrate and said sealing substrate.
